(19) United States
(12) Patent Application Publication
(10) Pub. No.: US 2012/0242937 A1
(43) Pub. Date: Sep. 27, 2012

(54) ELECTRO-OPTIC DEVICE AND METHOD FOR MANUFACTURING SAME

(75) Inventors: Makoto Yamada, Osaka (JP); Yoshimasa Fujita, Osaka (JP)

(73) Assignee: SHARP KABUSHIKI KAISHA, Osaka-shi, Osaka (JP)

(21) Appl. No.: 13/499,905

(22) PCT Filed: Oct. 28, 2010
(86) PCT No.: PCT/JP2010/006373

§ 371 Date: Apr. 2, 2012

(30) Foreign Application Priority Data
Oct. 30, 2009 (JP) 2009-249674

(51) Int. Cl. H01L 51/52; G02F 1/1337; H01L 51/56

(52) U.S. Cl. 349/69; 257/88; 438/34; 257/40; 257/E51.021

(57) ABSTRACT

An electro-optic device (100) includes a conductive wiring board (110) on one surface of which a plurality of conductive wires (140) are arranged so as not to intersect with each other, and a plurality of optical elements (130) each of which is provided on the board (110), and in which an insulating base member (131), a lower electrode (132), a function layer (133), and an upper electrode (134) are sequentially formed on the board (110). In this device (100), the lower electrode (132) is electrically connected to one of the conductive wires (140); the upper electrode (134) is electrically connected to one of the conductive wires (140) which is not connected to the lower electrode (132); and each of the optical elements (130) is provided such that part of the optical element (130) overlaps with part of one or more of the conductive wires (140) in plan view.

### TECHNICAL FIELD

The present invention relates to electro-optic devices, such as organic EL devices and liquid crystal display devices which have a conductive wiring board, and methods for manufacturing the electro-optic devices.

### BACKGROUND ART

Examples of the electro-optic devices which can be used as a flat-type light source include, for example, illuminating devices such as an organic EL illuminating device, an inorganic EL illuminating device, a plasma illuminating device, and a field emission lamp (FEL), and display devices such as a liquid crystal display device, an organic EL display device, an inorganic EL display device, a plasma display device, an electrophoretic display (EPD) device, and a field emission display (FED) device.

With higher complexity and higher definition of the electro-optic devices, more wires need to be provided on a mounting board. Thus, conductive wires are formed in a multilayer structure by alternately layering a conductive wire and an insulating layer to obtain a high density wiring pattern.

For example, Patent Document 1 discloses a structure in which a plurality of conductive wires are formed on one surface of a substrate, and through holes are formed such that the plurality of conductive wires may serve as the bottom surfaces of the through holes, and a bonding jumper is formed with a conductive paste curing material to connect the other surface of the substrate and each of the surfaces of the plurality of conductive wires, that is, the bottom surfaces of the through holes.

Patent Document 2 discloses a method of manufacturing a multilayered wiring board in which an insulating layer and a conductive pattern are alternately layered.

Patent Document 3 discloses a wiring board fabrication method including a step of forming one of a plurality of conductive patterns, a step of forming the other conductive patterns which are spaced apart from the one conductive pattern and by which the one conductive pattern is sandwiched, a step of covering a portion of the one conductive pattern which is sandwiched between the other conductive patterns with an insulating material, and a step of electrically connecting between the other conductive patterns by electroless plating. According to Patent Document 3, the above method allows the other conductive patterns to be conductive in a simple way.

### CITATION LIST

### Patent Document

Patent Document 1: Japanese Patent Publication No. 2008-205125
Patent Document 2: Japanese Patent Publication No. H08-222834
Patent Document 3: Japanese Patent Publication No. 2006-186154

### SUMMARY OF THE INVENTION

### Technical Problem

However, in the structures disclosed in Patent Documents 1-3, a plurality of conductive wires intersect one another, and therefore, the thickness is increased by the layered conductive wires, as well as by the insulating layer for insulating the conductive wires from one another. This may prevent a reduction in the thickness and the size of the device as a whole.

Further, a step of forming a conductive wire needs to be repeated several times so that conductive wires are layered in a multilayer structure. As a result, the fabrication process may become complicated, and the fabrication cost may be increased.

One of the objectives of the present invention is to reduce the size and the thickness of an electro-optic device having a conductive wiring board, simplify a fabrication process, and reduce fabrication cost.

### Solution to the Problem

An electro-optic device of the present invention includes a conductive wiring board on one surface of which a plurality of conductive wires are arranged so as not to intersect with each other, and a plurality of optical elements each of which is provided on the conductive wiring board, and in which an insulating base member, a lower electrode, a function layer, and an upper electrode are sequentially formed on the conductive wiring board, wherein the lower electrode is electrically connected to one of the plurality of conductive wires, the upper electrode is electrically connected to one of the plurality of conductive wires which is not connected to the lower electrode, and each of the plurality of optical elements is provided such that part of the optical element overlaps with part of one or more of the conductive wires in plan view.

According to this structure, the conductive wires are arranged so as not to intersect with each other. Therefore, it is possible to reduce the size of the conductive wiring board, compared to the case where the conductive wires are layered in a multilayer structure. If the conductive wires are layered in a multilayer structure, it is necessary to provide an insulating layer for separating the layered conductive wires from one another. However, since the conductive wires do not intersect with each other, and are provided in a single layer, a step of forming the insulating layer can be omitted, and moreover, the conductive wires can be obtained by performing a step, e.g., photolithography, only once. Accordingly, it is possible to reduce the takt time and fabrication costs. Further, since the electro-optic device is formed using the conductive wiring board on which the plurality of conductive wires are arranged so as not to intersect with each other, the size of the electro-optic device as a whole can be reduced.

It is preferable that the plurality of conductive wires are arranged so as to extend in parallel with each other.

According to this structure, since the plurality of conductive wires are arranged so as to extend in parallel with each other, the structure is not complex, and the conductive wires can be placed with a certain space between each other.

The electro-optic device of the present invention is preferably such that each of the plurality of optical elements has an elongated shape, and the plurality of conductive wires are arranged so as to extend in a direction orthogonal to a length direction of the plurality of optical elements.

According to this structure, the plurality of conductive wires and the plurality of optical elements can be placed without complexity. Thus, the conductive wires and the light emitting elements can be electrically connected easily.

The electro-optic device of the present invention is preferably such that the insulating base member is made of a flexible material.

According to this structure, since the insulating base member is made of a flexible material, it is possible to provide the optical elements on the conductive wiring board in a shape other than a planar plate shape, and increase design variations of the electro-optic device.

The conductive wiring board may be made of a flexible material.

The electro-optic device of the present invention is preferably such that the plurality of optical elements are placed in an enclosed space formed between the conductive wiring board and a substrate facing the conductive wiring board.

According to this structure, the optical elements are placed in an enclosed space formed between the conductive wiring board and a substrate facing the conductive wiring board. Thus, even if the optical elements do not have a gas barrier structure, it is possible to prevent gas, such as oxygen, from entering from the outside. Since it is not necessary to provide a gas barrier structure to each of the optical elements, costs can be reduced as well.

The electro-optic device of the present invention may be such that the function layer is an organic EL layer, and the plurality of optical elements are organic EL illuminators.

In this case, each of the insulating base member and the lower electrode may be made of an optically transparent material.

It is preferable that the organic EL illuminators are placed in an enclosed space formed between the conductive wiring board and a substrate facing the conductive wiring board, and at least one of the conductive wiring board or the substrate is made of an optically transparent material.

The electro-optic device of the present invention may be such that a diffusion resin layer having a light diffusion function is provided to a light extraction side of each of the organic EL illuminators.

The diffusion resin layer may be a diffuser plate.

Further, a wavelength conversion layer for converting a wavelength of light may be provided to the light extraction side of each of the organic EL illuminators.

The electro-optic device of the present invention may be such that the space between the conductive wiring board and the substrate is filled with a heat dissipating resin whose heat conductivity is higher than a heat conductivity of air.

The insulating base member may be made of a material having a light diffusion property.

The organic EL layer may include a charge generation layer.

The electro-optic device of the present invention may be used for illumination.

In such a case, it is preferable that the plurality of conductive wires are driven independently of each other, thereby making it possible to adjust light emission of the electro-optic device as a whole.

The electro-optic device of the present invention may be used for a display.

The function layer of the electro-optic device of the present invention may be a liquid crystal layer.

A method for manufacturing an electro-optic device including: a conductive wiring board on one surface of which a plurality of conductive wires are arranged so as not to intersect with each other; and a plurality of organic EL elements each of which is provided on the conductive wiring board, and in which an insulating base member, a lower electrode, an organic EL layer, and an upper electrode are sequentially formed on the conductive wiring board, wherein the lower electrode is electrically connected to one of the plurality of conductive wires, the upper electrode is electrically connected to one of the plurality of conductive wires which is not connected to the lower electrode, and each of the plurality of organic EL elements is provided such that part of the organic EL element overlaps with part of one or more of the conductive wires in plan view, the method including: performing processes for forming the organic EL layer and the upper electrode on the insulating base member conveyed by a roll-to-roll method.

According to this method, the electrodes and the organic EL layer can be continuously formed in one fabrication chamber. This results in a simple fabrication process, and a reduction in size of a fabrication device.

### Advantages of the Invention

According to the present invention, the plurality of conductive wires are arranged on one surface so as not to intersect with each other. Therefore, it is possible to reduce the size and the thickness of the conductive wiring board, compared to the case where the conductive wires are layered in a multilayer structure. If the conductive wires are layered in a multilayer structure, it is necessary to provide an insulating layer for separating the layered conductive wires from one another. However, since the plurality of conductive wires do not intersect with each other, and are provided in a single layer, a step of forming the insulating layer can be omitted, and moreover, the conductive wires can be obtained by performing a step, e.g., photolithography, only once. Accordingly, it is possible to reduce the takt time and fabrication costs. Further; insulating base members are provided on the surfaces of the plurality of optical elements which face the conductive wiring board. Therefore, even in the case where the plurality of conductive wires are arranged so as not to intersect with each other, and are provided in a single layer, it is possible to obtain a conductive wiring board with a complex conductive pattern by connecting the lower electrode with one of the plurality of conductive wires, and connecting the upper electrode with a conductive wire different from the one connected to the lower electrode. Thus, it is possible to reduce the size and the thickness of the electro-optic device as a whole, which is fabricated using the conductive wiring board provided with a plurality of conductive wires arranged so as not to intersect with each other.

### BRIEF DESCRIPTION OF THE DRAWINGS

FIG. 1 is a plan view of an organic EL illuminating device according to the first embodiment.

FIG. 2 is a cross-sectional view taken along the line of FIG. 1.

FIG. 3 is a cross-sectional view taken along the line III-III of FIG. 1.

FIG. 4 is a cross-sectional view of an organic EL illuminator in the width direction.

FIG. 5 is an organic EL illuminating device according to a variation of the first embodiment.

FIG. 6 is an organic EL illuminating device according to a variation of the first embodiment.

FIG. 7 is an organic EL illuminating device according to a variation of the first embodiment.

FIG. 8 is an organic EL illuminating device according to a variation of the first embodiment.

FIG. 9 is an explanation drawing for showing a method for manufacturing the organic EL illuminator according to the first embodiment.

FIG. 10 is an explanation drawing for showing a method for manufacturing the organic EL illuminating device according to the first embodiment.

FIG. 11 is a cross-sectional view of a liquid crystal display device according to the second embodiment.

FIG. 12 is a cross-sectional view of a liquid crystal display element according to the second embodiment.

### DESCRIPTION OF EMBODIMENTS

### First Embodiment

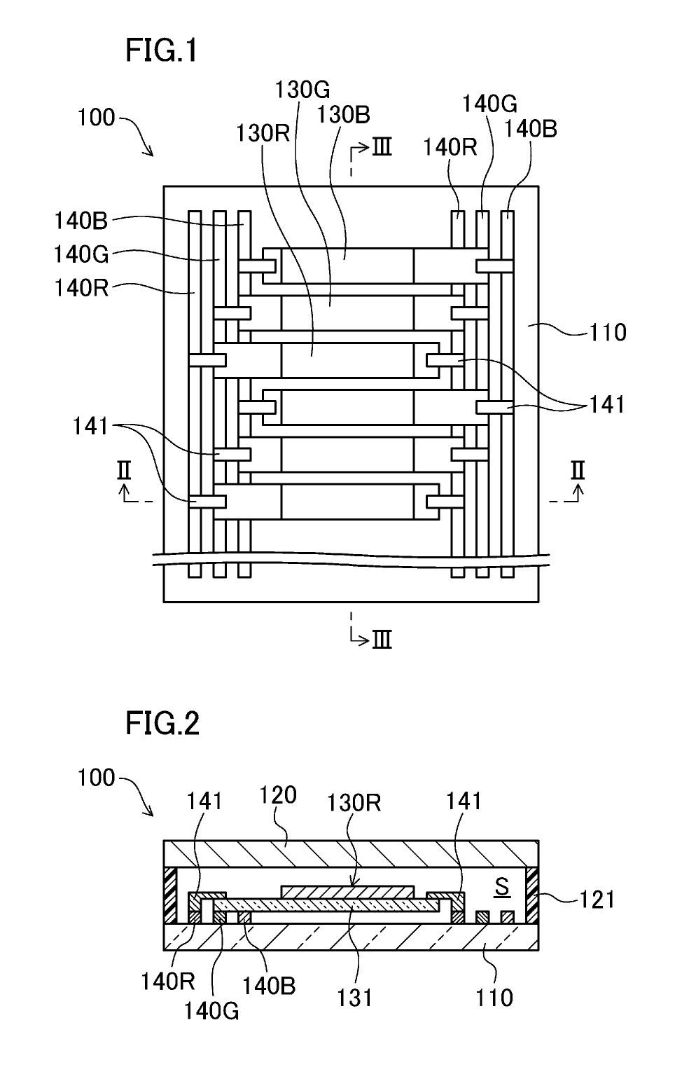

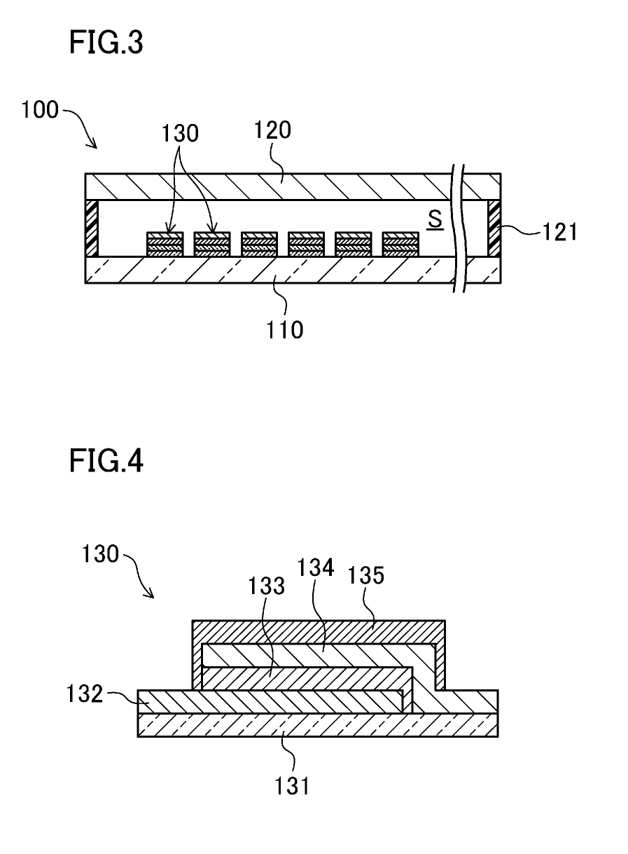

An organic EL illuminating device as an embodiment of an electro-optic device will be described in detail below, based on the drawings. FIGS. 1-3 show an organic EL illuminating device 100 according to the first embodiment. The organic EL illuminating device 100 is used, for example, as office lighting, store lighting, facility lighting, stage lighting and set lighting, exterior lighting, residential lighting, display lighting (used, for example, for a pachinko machine, a vending machine, and a freezer/refrigerator showcase), lighting such as built-in lighting in equipment/furniture, a liquid crystal panel backlight, illuminations, neon, a luminous source for signs.

The organic EL illuminating device 100 has a structure in which a first substrate 110 and a second substrate 120 are provided to face each other, and a plurality of organic EL illuminators 130 are provided on a surface of the first substrate 110 in the enclosed space S formed between the substrates.

Here, it is not necessary to provide a plurality of organic EL illuminators 130, but one organic EL illuminator 130 may be provided and sealed between the first substrate 110 and the second substrate 120.

FIG. 4 is an organic EL illuminator 130.

Each of the organic EL illuminators 130 has a structure in which a first electrode 132 (a lower electrode), an organic EL layer 133, a second electrode 134 (an upper electrode), and a protection film 135 are sequentially layered on an insulating base member 131. The organic EL illuminator 130 is electrically connected to a conductive wire 140 provided on the first substrate 110 via a connecting wiring 141, and light can be generated by applying a′ voltage between the first electrode 132 and the second electrode 134. The organic EL illuminator 130 is in the shape, for example, of an elongated, rectangular planar plate having a width of about 30 mm, a length of about 160 mm, and a thickness of about 0.7 mm, for example. The plurality of organic EL illuminators 130 may be in the same shape, or may have different widths, for example. The plurality of organic EL illuminators 130 are arranged, for example, such that a plurality of units, each unit including three organic EL illuminators, i.e., a red organic EL illuminator 130R, a green organic EL illuminator 130G, and a blue organic EL illuminator 130B, are repeatedly arranged. The organic EL illuminators 130 may include three types (i.e., RGB), or may include two types (i.e., a blue organic EL illuminator and an orange organic EL illuminator), or may include only one type (for example, single-color, such as a red color, organic EL illuminator), or may have another structure.

The insulating base member 131 is made of an insulating material. Examples of the material of the insulating base member 131 include, for example, a transparent plastic film, such as films made of drawn polypropylene (OPP), polyethylene naphthalate (PEN), polyethylene terephthalate (PET), and polyphenylene sulfide (PPS), and a glass substrate. It is preferable to provide a protection film, such as a silicon oxide film, on the surface of the insulating base member 131. The provision of the protection film can prevent alkali oxide from being released from inside the insulating base member 131. Further, the insulating base member 131 may be insulating by forming the base with a light-reflecting material such as a metal film, and covering the surface with an insulating film made of synthetic resin, such as epoxy resin and silicon nitride (SiNx). If the insulating film is made of a silicon nitride film, the insulating film is formed to have a thickness of about 500 nm using, for example, a plasma CVD apparatus. A flexible material such as a plastic film is preferable as a material for the insulating base member 131. If such the material is used, the organic EL illuminators 130 can be provided on the conductive wiring board having a curved surface, which leads to an increase in design variations of the illuminating device as a whole.

The insulating base member 131 may contain a material having a light diffusion property. Examples of the material having a light diffusion property include: acrylic particles, such as methyl methacrylate, ethyl methacrylate, isobutyl methacrylate, n-butyl methacrylate, n-butyl methyl methacrylate, methyl acrylate, and a copolymer or a terpolymer of these substances; olefinic particles, such as polyethylene, polystyrene (PS), and polypropylene; particles made of acrylic and olefinic copolymers; and multilayer multicomponent particles obtained by coating the top of homopolymer particles with a different kind of monomers. Accordingly, an organic EL device having a microcavity (microresonator) structure is formed, and thus, it is possible to improve the color purity and the luminous efficacy, and possible to increase viewing angle.

For example, the first electrode 132 serves as a positive electrode, and the second electrode 134 serves as a negative electrode. However, the organic EL illuminator may have an inverted structure in which the first electrode 132 serves as a negative electrode and the second electrode 134 serves as a positive electrode. Examples of the material for the positive electrode include indium tin oxide (ITO), indium zinc oxide (IZO (registered trade mark)), etc. Examples of the material for the negative electrode include alkali metal and alkali earth metal, for example, and the negative electrode is preferably made of a calcium film, an aluminum film, a layered film of a calcium film and an aluminum film, a magnesium alloy film, a barium film, a barium compound film, a cesium film, a cesium compound film, a fluorine compound film, etc., in terms of safety. In the first embodiment, the organic EL illuminator 130 has a bottom emission structure. Thus, it is preferable that the first electrode 132 is made of an optically transparent or optically semi-transparent material, and that the second electrode 134 is made of a light-reflecting material. On the other hand, if the organic EL illuminator has a top emission structure, the first electrode is made of a light-reflecting material, and the second electrode is made of an optically transparent or optically semi-transparent material.

The organic EL layer 133 includes at least an emitting layer. The organic EL layer 133 may have a three-layer structure in which a hole transport layer, an emitting layer, and an electron transport layer are layered, or a five-layer structure in which a hole injection layer, a hole transport layer, an emitting layer, an electron transport layer, and an electron injection layer are layered, or a six-layer structure in which a hole injection layer, a hole transport layer, an electron blocking layer, an emitting layer, a hole blocking layer, and an electron injection layer are layered.

The hole injection layer and the hole transport layer have a function of efficiently injecting and transporting holes received from the positive electrode. Examples of a material for hole injection include, for example, a material represented by

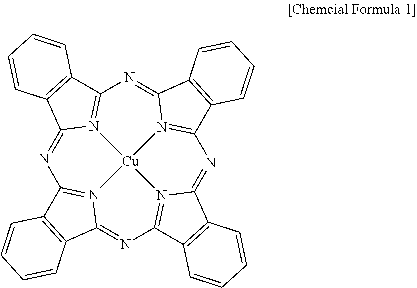

which is copper phthalocyanine (CuPc). Examples of a material for the hole transport include, for example, aromatic tertiary amines such as 4′-bis[N-(1-naphtyl)-N-phenylamino]biphenyl (α-NPD) represented by

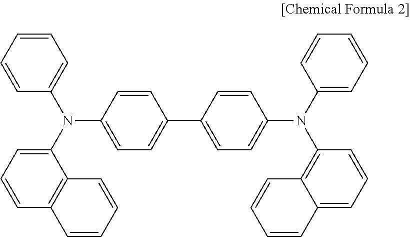

The hole injection layer and the hole transport layer have a thickness, for example, of about 30 nm and about 20 nm, respectively.

Examples of an electron blocking material of the electron blocking layer include, for example, a material represented by

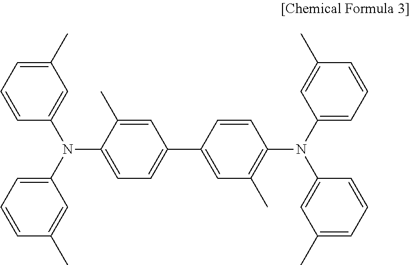

which is 4,4′-bis-[N,N′-(3-tolyl)amino-3,3′-dimethylbiphenyl (HMTPD). The electron blocking layer has a thickness, for example, of about 10 nm.

The emitting layer is made of a material which is obtained by injecting a dopant in the hole transport material and the electron transport material, and through which both holes and electrons can be transported. Examples of a red phosphorescent light emitting dopant include, for example, a material represented by

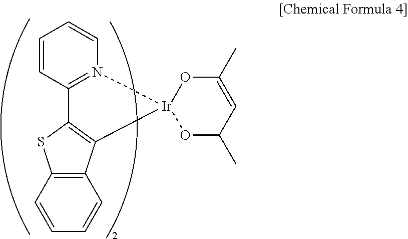

which is bis(2-(2′-benzo[4,5-a]thienyl)-pyridinato-N,C₃′)iridium(acetylacetonate) ((Btp)₂Ir(acac)). The red color emitting layer has a thickness, for example, of about 20 nm.

Examples of a green phosphorescent light emitting dopant include, for example, a material represented by

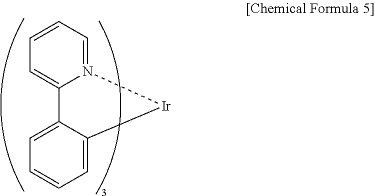

which is (2-phenylpyridine)iridium (Ir(ppy)₃). The green color emitting layer has a thickness, for example, of about 20 nm.

Examples of a blue phosphorescent light emitting dopant include, for example, a material represented by

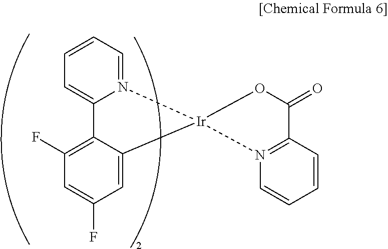

which is iridium(III)bis(4′,6′-difluorophenyl)-pyridinato-N,C2]picolinate (FIr(pic)). The blue color emitting layer has a thickness, for example, of about 10 nm.

The hole blocking layer has a function of blocking holes from moving to the negative electrode. Examples of the hole blocking material include, for example, a material represented by

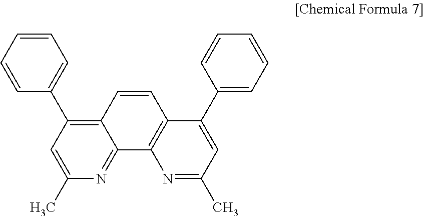

which is 2,9-dimethyl-4,7-diphenyl-1,10-phenanthroline (BCP). The hole blocking layer has a thickness, for example, of about 10 nm.

The electron injection layer and the electron transport layer have a function of efficiently injecting and transporting electrons received from the negative electrode to the emitting layer. Examples of a material for the electron transport include, for example, a material represented by

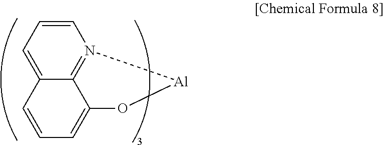

which is tris(8-quinolinyloxy) aluminum (Alq3), and

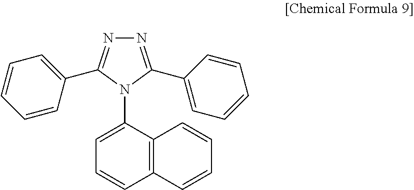

which is 3-phenyl-4(1′-naphthyl)-5-phenyl-1,2,4-triazole (TAZ). Examples of a material for the electron injection include, for example, lithium fluoride (LiF). The electron transport layer and the electron injection layer have a thickness, for example, of about 30 nm and about 1 nm, respectively.

The organic EL layer 133 may include a charge generation layer. In this case, the organic EL layer 133 is formed, for example, by sequentially layering a hole transport layer, an emitting layer, a charge generation layer, a hole transport layer, an emitting layer, and a charge transport layer from the positive electrode side. That is, the organic EL layer 133 can be an organic EL illuminator having a plurality of emitting layers. Examples of a material for the charge generation layer include, for example, vanadium pentoxide (V₂O₅). Since the charge generation layer is provided between the organic EL layers, and forms an equipotential surface between adjacent emitting layers, the amount of current flowing is reduced while the drive voltage is increased. This results in the superior emission lifetime. The charge generation layer has a thickness, for example, of about 20 nm.

The protection film 135 is provided above the insulating base member 131 so as to cover the electrodes and the organic EL layer 133. Examples of a material for the protection film 135 include, for example, silicon oxynitride. The protection film 135 has a thickness, for example, of about 100 nm.

The organic EL illuminators 130 of all colors may have the same shape, or the organic EL illuminators 130 may have a different length and a width, depending on the color. It is possible to obtain an illuminating device superior in the luminance and the emission lifetime by freely determining the width in consideration of the properties, such as luminous efficacy, of the luminescent material of each luminescent color.

A diffusion resin layer having a light diffusion function may be provided on the light extraction side of the organic EL illuminator 130 (on the insulating base member 131 in the case of the bottom emission type). The diffusion resin layer is made of binder resin containing a plurality of light-diffusing particles. Examples of the binder resin include an acrylic resin, a polyester resin, a polyolefin resin, and a polyurethane resin. Examples of the light-diffusing particles include the light-diffusing particles described as those which may be added to the insulating base member 131. Among such light-diffusing particles, polymethylmethacrylate (PMMA) is preferable for use. Since a plurality of such light-diffusing particles are contained in the binder resin, the light passing through the diffusion resin layer can be diffused uniformly in the entire surface of the insulating base member 131. This leads to an improvement in the viewing angle and the light extraction efficiency. As a result, the luminance is increased. The diffusion resin layer has a thickness, for example, of about 150 μm.

If the diffusion resin layer is provided on the light extraction side of the organic EL illuminator 130, the diffusion resin layer may be a diffuser plate. Materials made of substances similar to those listed as the binder resin forming the diffusion resin layer can be used for the diffuser plate. For example, acrylic resin in which light-diffusing fine particles are dispersed, such as cross-linked polymethylmethacrylate and cross-linked polystyrene, may be used for the diffuser plate.

Further, a wavelength conversion layer for converting the wavelength of light may be provided on the light extraction side of the organic EL illuminator 130. Examples of a material for the wavelength conversion layer include, for example, a YAG based inorganic fluorescent material, an organic fluorescent material typically represented by the materials for the organic EL element described above, and other fluorescent materials. The wavelength conversion layer has a thickness, for example, of about 100 μm. With this structure, the wavelength of light can be converted to a desired wavelength.

The organic EL illuminators 130 having the above structure are arranged on the first substrate 110 such that one end and the other end of each of the organic EL illuminators 130 are electrically connected to corresponding ones of the conductive wires 140, as shown in FIG. 1.

The first substrate 110 and the second substrate 120 are made of a transparent material, such as glass substrate, a resin substrate, etc., or a material not transparent, such as a metal member. At least one of the first substrate 110 or the second substrate 120 is made of an optically transparent material. The first substrate 110 and the second substrate 120 may be in the shape of a planar plate or may have a shape with a curved surface. The first substrate 110 and the second substrate 120 may be made of a flexible material such as PET, PEN, etc. In such a case, it is possible to increase design variations of the organic EL illuminating device 100. An organic-inorganic hybrid layer, a multilayer film of an organic layer and an inorganic layer, etc., may be formed on surfaces of the flexible materials to increase gas barrier properties and machine strength, and reduce gas permeation. The first substrate 110 and the second substrate 120 may each have, for example, a length of about 200 mm, a width of about 200 mm, and a thickness of about 0.7 mm.

The first substrate 110 and the second substrate 120 are arranged to face each other, with the organic EL illuminators 130 sandwiched therebetween. The first substrate 110 and the second substrate 120 are sealed by a resin 121, such as a heat curable resin, a UV curable resin, etc., to encapsulate the organic EL illuminators 130. A space S formed by the first substrate 110 and the second substrate 120 is adjusted to an inert gas atmosphere (e.g., nitrogen, argon, etc.) or a vacuum atmosphere. Since the first substrate 110 and the second substrate 120 are sealed and the enclosed space S is formed between the substrates, it is possible to prevent moisture or oxygen from entering into the organic EL layer 133 of each organic EL illuminator 130 from the outside, without providing gas barrier properties to each of the organic EL illuminators 130. The two substrates may be attached to each other by laser bonding, other than by being sealed with resin. Further, the two substrates may be sealed, with a spacer provided between the substrates. In such a case, it is possible to control the distance between the first substrate 110 and the second substrate 120. The space S formed between the first substrate 110 and the second substrate 120 may contain, for example, a moisture absorbent, such as barium oxide, etc. The space S formed between the first substrate 110 and the second substrate 120 may be filled with, for example, a heat dissipating resin having a high heat conductivity. Examples of the heat dissipating resin material include, for example, an insulating acrylic rubber, ethylene propylene rubber, etc. The high-heat-conductivity heat dissipating resin allows heat to efficiently escape to the outside and be more uniformly distributed in a plane.

The first substrate 110 is provided with a plurality of conductive wires 140 on the surface on which the organic EL illuminators 130 are arranged. The plurality of conductive wires 140 are arranged, for example, in parallel to each other and extend in the width direction of the organic EL illuminators 130, that is, in a direction orthogonal to the length direction of the organic EL illuminators 130 as shown in FIG. 1. Each of the conductive wires 140 is made of a material which forms the first electrode 132 and the second electrode 134 of the organic EL illuminator 130, such as ITO, IZO, etc. Each of the conductive wires 140 has, for example, a width of about 2 mm, a length of about 200 mm, and a thickness of about 150 nm.

Two conductive wires 140 are paired. One of a pair is electrically connected to the first electrode 132, and the other of the pair is electrically connected to the second electrode 134 of the corresponding one of the organic EL illuminators 130. A voltage can be applied to the organic EL illuminator 130 by allowing a current to flow in the pair of conductive wires 140. It is preferable that the pairs of the conductive wires 140 can be driven independently of one another by applying a voltage independently. This allows the organic EL illuminators 130 connected to each pair of conductive wires 140 to be driven independently of one another, thereby making it possible to adjust light intensity, color tone, etc. Specifically, the red organic EL illuminator 130R is connected to the conductive wires 140R; the green organic EL illuminator 130G is connected to the conductive wires 140G; and the blue organic EL illuminator 130B is connected to the conductive wires 140B, to make it possible to adjust light intensity, color tone, etc., of each of the luminescent colors.

The conductive wires 140 are electrically connected to the corresponding one of the organic EL illuminators 130 by, for example, connecting wirings 141 made of lead-free solder, silver paste, etc. The connecting wirings 141 are provided in contact with the surface of the organic EL illuminator 130 which is opposite to the surface facing the conductive wiring board (i.e., the first substrate 110). Since the organic EL illuminator 130 is electrically connected to the conductive wires 140 by the connecting wirings 141 provided in contact with the surface of the organic EL illuminator 130 opposite to the surface facing the conductive wiring board, the surface of the organic EL illuminator 130 facing the conductive wiring board can be insulated. Thus, even if a plurality of conductive wires 140 are formed on the conductive wiring board, with no insulating layer interposed between the conductive wiring board 110 and the conductive wire 140, a current does not flow between an organic EL illuminator 130 and the conductive wires 140 which are not intended for conduction with the organic EL illuminator 130.

An auxiliary electrode may be provided along the length direction of the strip-shaped organic EL illuminators 130. With this structure, a voltage drop due to the resistance of the electrodes can be reduced. Thus, it is possible to prevent light emitting unevenness. The auxiliary electrode may cover all or part of the organic EL illuminators 130.

Other than providing the organic EL illuminators 130 of the three luminescent colors in parallel to each other, the organic EL illuminators 130 may be provided such that base units, each including regions emitting three luminescent colors, may be arranged in the L shape, may be arranged radially, or may be arranged in other layouts.

The organic EL illuminators 130 may be arranged such that the surface closer to the insulating base member 131 is in contact with the first substrate 110, or may be arranged such that the surface closer to the second electrode 134 which is opposed to the surface closer to the insulating base member 131 is in contact with the first substrate 110. In the case where the surface closer to the second electrode 134 of the organic EL illuminator 130 is in contact with the first substrate 110, the second electrode 134 is a lower electrode, and the first electrode 132 is an upper electrode. An insulating film for insulating between the conductive wire 140 on the first substrate 110 and the organic EL illuminator 130 is provided on the surface of the second electrode 134. The protection film 135 covering the second electrode 134 may serve as the insulating film, or another insulating film may be provided to cover the protection film 135.

In the first embodiment, the organic EL illuminators 130 of the respective luminescent colors are arranged next to each other. Alternatively, the organic EL illuminator 130 may have a tandem structure in which emitting layers of the respective colors are layered.

In the organic EL illuminating device 100 of the first embodiment, the plurality of conductive wires 140 formed on the conductive wiring board do not intersect with each other. Therefore, it is possible to reduce the size and the thickness of the conductive wiring board, compared to the case where the conductive wires 140 are layered in a multilayer structure. If the conductive wires 140 are layered in a multilayer structure, it is necessary to provide an insulating layer for separating the layered conductive wires 140 from one another. However, since the conductive wires 140 do not intersect with each other, and are provided in a single layer, a step of forming the insulating layer can be omitted, and moreover, the conductive wires 140 can be obtained by performing a step, e.g., photolithography, only once. Accordingly, it is possible to reduce the takt time and fabrication costs. Further, the surfaces of the plurality of organic EL illuminators 130 which face the conductive wiring board are made of an insulating material. Therefore, even in the case where the plurality of conductive wires 140 are arranged so as not to intersect with each other, and are provided in a single layer, it is possible to obtain a conductive wiring board with a complex conductive pattern by connecting the first electrode 132 with one of the plurality of conductive wires 140, and connecting the second electrode 134 with a conductive wire 140 different from the one connected to the first electrode 132. Since the organic EL illuminating device 100 is fabricated using the conductive wiring board on which the plurality of conductive wires 140 are arranged so as not to intersect with each other, the size and the thickness of the organic EL illuminating device 100 as a whole can be reduced.

In the first embodiment, the organic EL illuminators 130 are provided only on the first substrate 110. However, the organic EL illuminators 130 are not limited to this structure, but may be provided, for example, on both of the first substrate 110 and the second substrate 120. Further, in the first embodiment, the organic EL illuminators 130 are arranged such that the surface closer to the insulating base member 131 is in contact with the first substrate 110. However, the organic EL illuminators 130 are not limited to this structure, but may be arranged such that the surface closer to the second electrode 134 is in contact with the substrate.

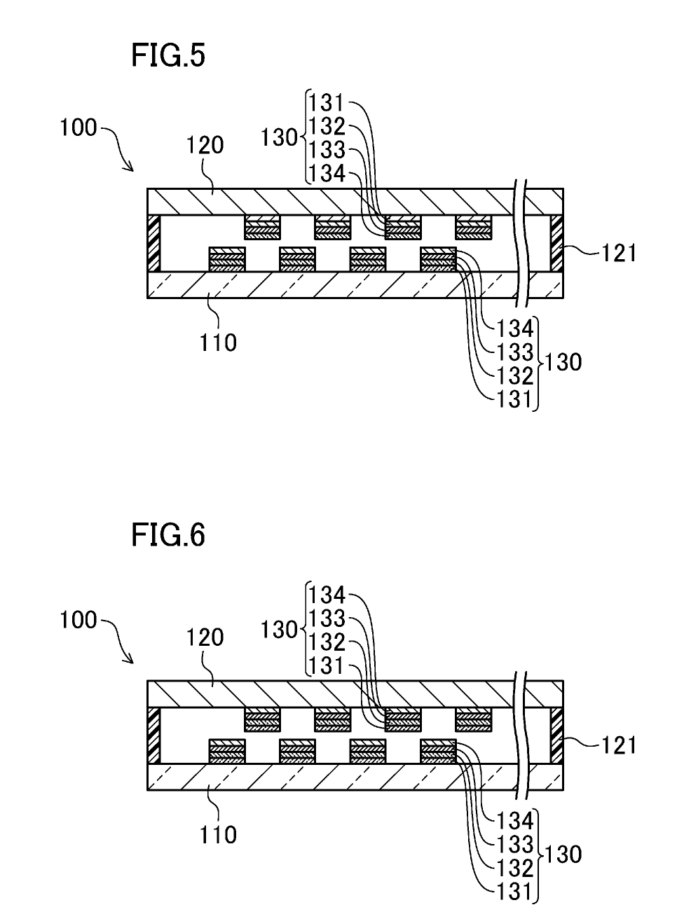

For example, as shown in FIG. 5, if the first substrate 110 is made of a transparent material, and the second substrate 120 is made of a light-reflecting material, the bottom emission type organic EL illuminators 130 may be provided such that the surface closer to the insulating base member 131 is in contact with the first substrate 110, and the top emission type organic EL illuminators 130 may be provided such that the surface closer to the insulating base member 131 is in contact with the second substrate 120. Here, the organic EL illuminators 130 on the first substrate 110 and the organic EL illuminators 130 on the second substrate 120 do not overlap one another. Therefore, it is possible to substantially increase the light-emitting area of the organic EL illuminating device 100 as a whole.

Other than providing the top emission type organic EL illuminators 130 on the second substrate 120, the bottom emission type organic EL illuminators 130 may be provided such that the surface closer to the second electrode 134 is in contact with the second substrate 120 as shown in FIG. 6.

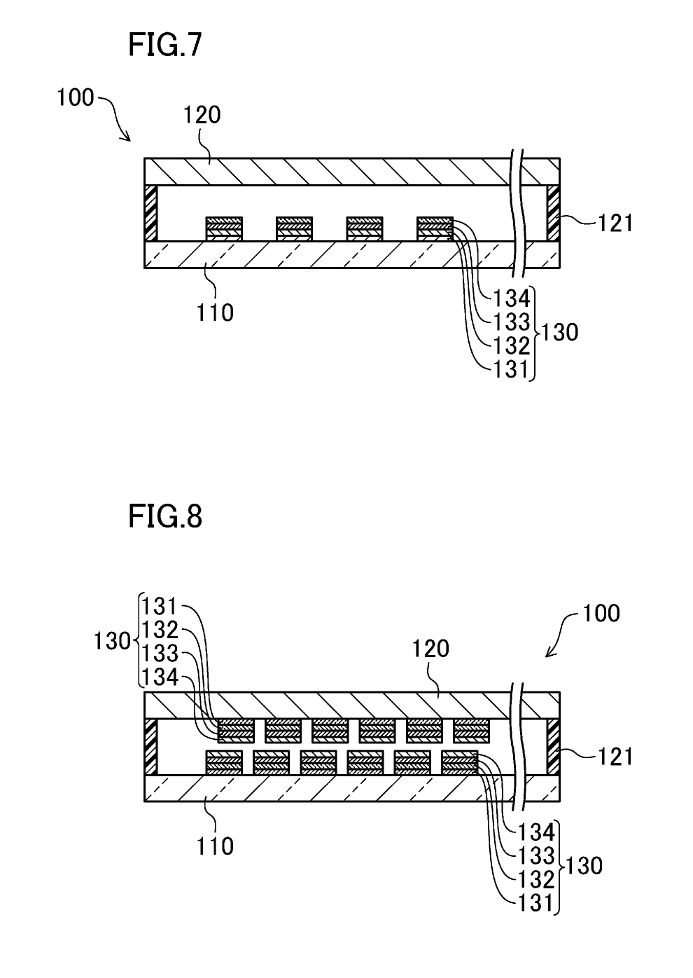

In the first embodiment, the organic EL illuminators 130 are arranged on the first substrate 110 such that the light extraction side of each of the organic EL illuminators 130 faces the transparent first substrate 110. However, the organic EL illuminators 130 may be provided such that the side opposing the light extraction side faces the transparent first electrode 132 as shown in FIG. 7. In this case, the light extracted from the organic EL illuminators 130 is reflected by the light-reflecting second substrate 120, and the reflected light is emitted from the first substrate 110. That is, the illuminating device can be an indirect lighting unit.

Further, the organic EL illuminating device 100 can be a double-sided illumination by using transparent substrates as the first substrate 110 and the second substrate 120, and providing the organic EL illuminators 130 on both of the transparent substrates as shown in FIG. 5.

In the first embodiment, the organic EL illuminators 130 are sealed between the first substrate 110 and the second substrate 120 facing each other. However, the organic EL illuminators 130 are not limited to this structure, but may be sealed in a space having, for example, a columnar shape, a rectangular parallelepiped shape, a sphere shape, etc., formed by three substrates or more.

<Method for Manufacturing Organic EL Illuminating Device>

Next, a method for fabricating the organic EL illuminating device 100 of the present embodiment will be described.

(Fabrication of Organic EL Illuminator)

First, a first electrode 132, an organic EL layer 133, a second electrode 134, etc., are sequentially formed on an insulating base member 131 to form an organic EL illuminator 130. It is preferable that the organic EL illuminator 130 is formed in an atmosphere where a moisture content is low, for example, in a glovebox, etc., in a dry air atmosphere.

—Formation of First Electrode—

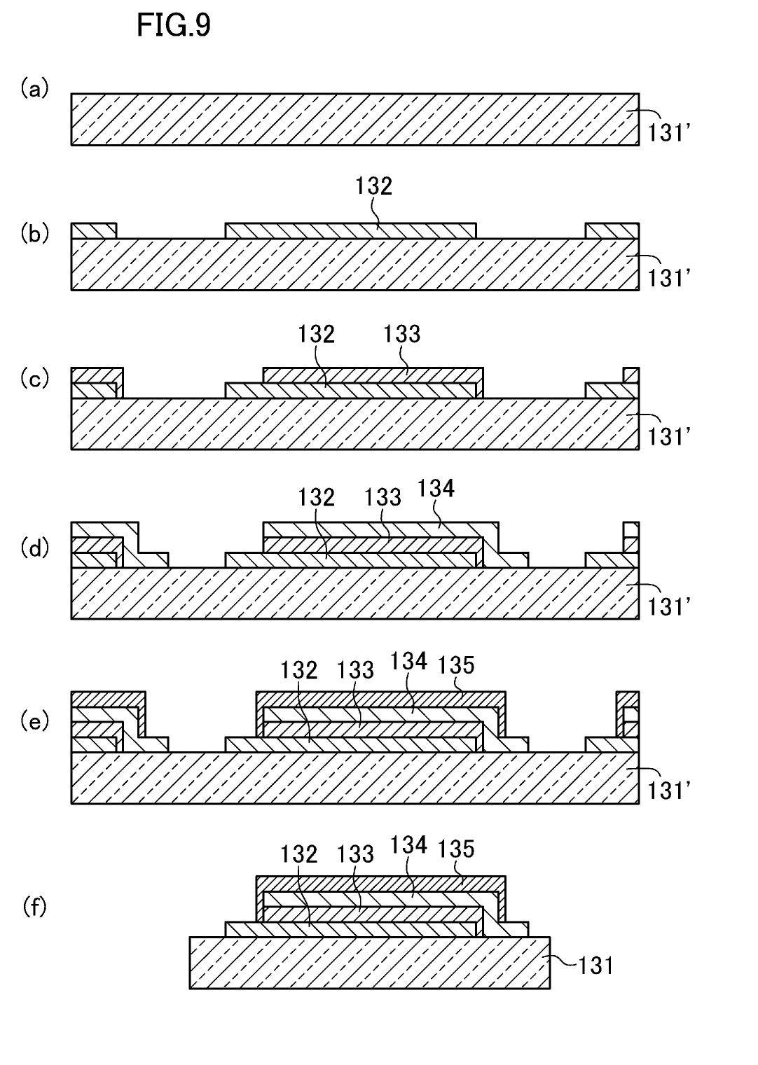

As shown in FIG. 9(b), an ITO film (e.g., a thickness of 150 nm) to be a first electrode 132 is formed, for example, by sputtering on a film tape 131′ made, for example, of a PET film. Part of the ITO film is etched, for example, by laser ablation to obtain the first electrode 132. Then, a surface of the first electrode 132 is cleaned by ultrasonic cleaning and UV-ozone cleaning. As the ultrasonic cleaning, for example, cleaning is performed for about 10 minutes using acetone and IPA (isopropyl alcohol) as a cleaning solution. As the UV-ozone cleaning, for example, cleaning is performed for about 30 minutes using a UV-ozone cleaner. In the case where the insulating base member 131 is made of a metal plate, etc., a plasma CVD process, etc., is performed on the surface of the metal plate as an insulation process.

—Formation of Organic EL Layer—

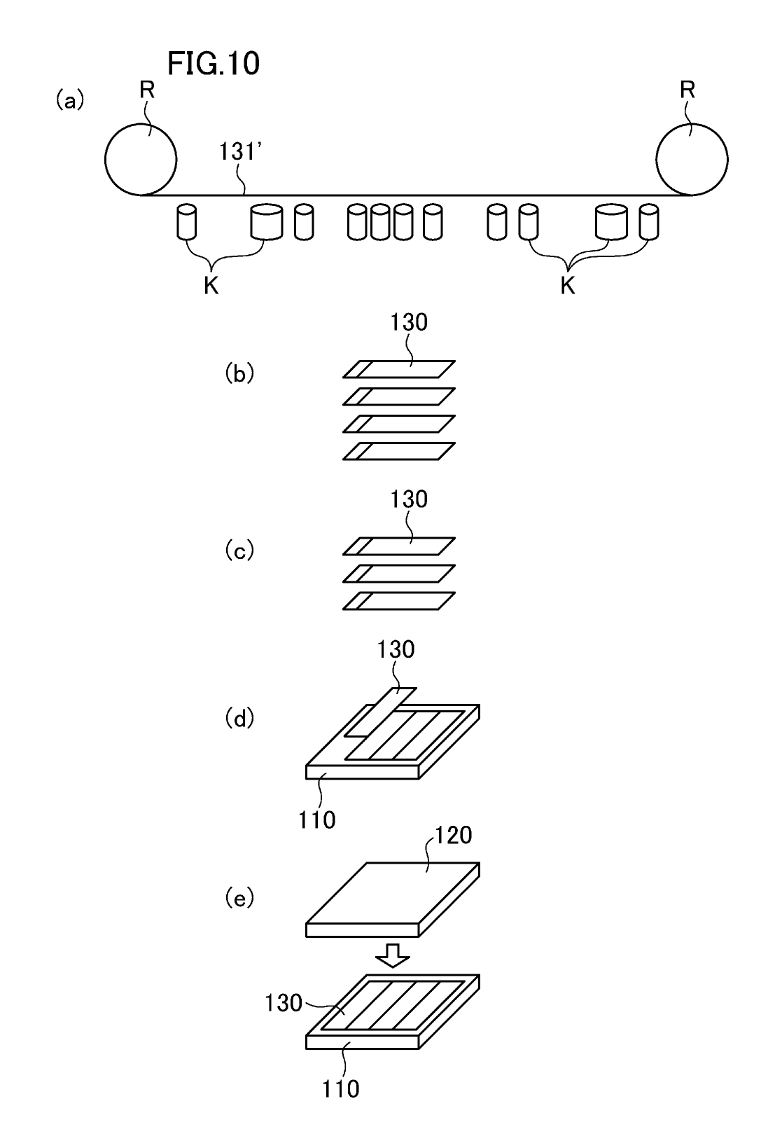

Next, the film tape 131′ on the surface of which the first electrode 132 has been formed is attached to a roll-to-roll vapor deposition device (or a reel-to-reel vapor deposition device) as shown in FIG. 10(a). The roll-to-roll vapor deposition device has two rolls R for winding the film tape 131′, and formation sections K for forming the respective organic layers, the second electrode, etc. The roll-to-roll vapor deposition device can convey the film tape 131′ such that the film tape 131′ passes the formation sections K at a constant speed of, for example, 1 msec.

In the respective organic layer formation sections K, a hole injection layer, a hole transport layer, an electron blocking layer, an emitting layer, a hole blocking layer, an electron transport layer, and an electron injection layer are formed, for example, by a vacuum deposition method as shown in FIG. 9(c).

In the case where a red color emitting layer is formed as an emitting layer, α-NPD (a hole hole transport material), TAZ (an electron transport material), and Btp₂Ir(acac) (a red phosphorescent light emitting dopant), for example, are co-deposited while the deposition speed rates of these materials are controlled to be 0.6:1.4:0.15.

In the case where a green emitting layer is formed as an emitting layer, α-NPD (a hole transport material), TAZ (an electron transport material), and Ir(ppy)₃ (a green phosphorescent light emitting dopant), for example, are co-deposited while the deposition speed rates of these materials are controlled to be 1.0:1.0:0.1.

In the case where a blue color emitting layer is formed as an emitting layer, α-NPD (a hole transport material), TAZ (an electron transport material), and Firpic (a blue phosphorescent light emitting dopant), for example, are co-deposited while the deposition speed rates of these materials are controlled to be 1.5:0.5:0.2.

—Formation of Second Electrode and Protection Film—

Next, an aluminum film (e.g., a thickness of 100 nm) to be a second electrode 134 is formed using a vacuum deposition method, etc., at a second electrode formation section K of the roll-to-roll vapor deposition device as shown in FIG. 9(d). After that, as shown in FIG. 9(e), an SiON film (e.g., a thickness of 100 nm) to be a protection film 135 is formed at a protection film formation section K. Then, the film tape 131′ on which the first electrode 132, the organic EL layer 133, the second electrode 134, and the protection film 135 are sequentially layered is wound around the rolls R of the roll-to-roll vapor deposition device.

—Cutting of Film Tape—

Next, as shown in FIG. 9(f), the film tape 131′ wound around the rolls R is cut into predetermined lengths.

Here, even if the organic EL illuminators 130 of the respective luminescent colors are displaced from each other in the length direction as shown in FIG. 1, the locations of the emission regions of the respective organic EL illuminators 130 can be aligned with each other in the length direction by making each of the organic EL illuminators 130 of the respective luminescent colors have a different margin length from the emission region to an end of the organic EL illuminator 130.

The organic EL illuminators 130 as shown in FIG. 10(b) are obtained in this manner. Here, testing of the obtained organic EL illuminators 130 is performed using a known technique, and a defective product(s) is removed as shown in FIG. 10(c).

Although a roll-to-roll vapor deposition device is used to form the organic EL illuminators 130 in the above descriptions, the device is not limited to the roll-to-roll vapor deposition device. However, it is preferable to use the roll-to-roll vapor deposition device, considering that the device is not large and superior in material use efficiency.

(Fabrication of Organic EL Illuminating Device)

Next, as shown in FIG. 10(d), the obtained organic EL illuminators 130 are placed on the first substrate 110. Prior to the placement, conductive wires 140 are formed on the first substrate 110, using a vacuum deposition method using a mask, a sputtering method, a photolithography technique, etc. Here, the conductive wires 140 are formed so as not to intersect with each other, and are provided in a single layer. Thus, complex procedures necessary for forming the conductive wires 140 in a multilayer structure are not necessary. Accordingly, it is possible to reduce the takt time and fabrication costs.

Subsequently, the organic EL illuminators 130 placed on the first substrate 110 are connected to the conductive wires 140 on the first substrate 110 via connecting wirings 141 made, for example, of lead-free solder.

Then, as shown in FIG. 10(e), the first substrate 110 on which the organic EL illuminators 130 are placed is covered by the second substrate 120, and the second substrate 120 is fixed. The second substrate 120 can be fixed by a UV curable resin, for example. Examples of the UV curable resin include, for example, an epoxy resin (e.g., 30Y-332 manufactured by ThreeBond Co., Ltd.).

The organic EL illuminating device 100 is formed in this manner.

### Second Embodiment

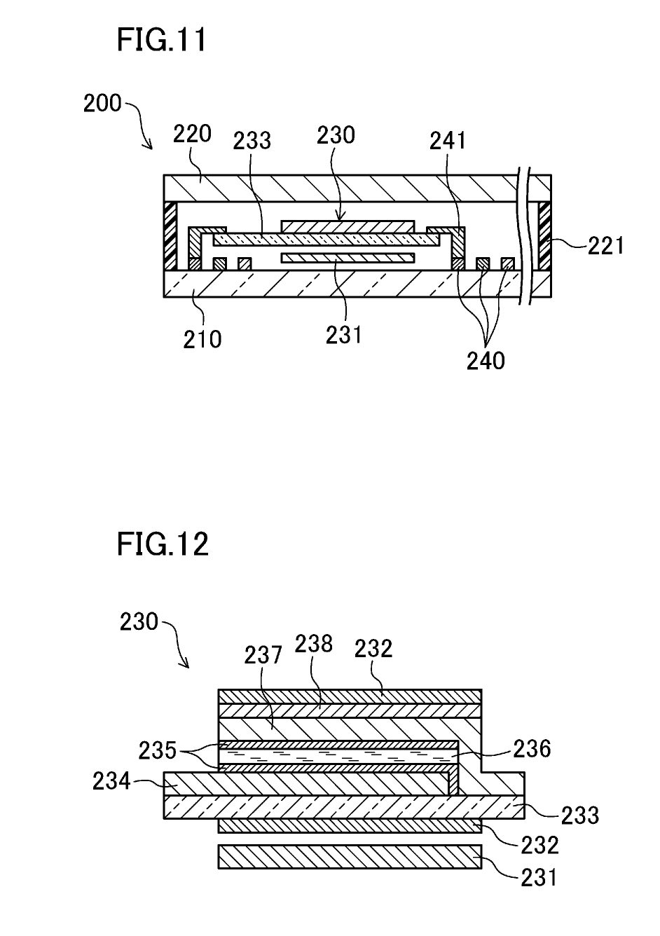

FIG. 11 shows a liquid crystal display device 200 according to the second embodiment. The liquid crystal display device 200 is used, for example, as a large display for a television, a small display for a portable device, etc.

The liquid crystal display device 200 has a structure in which a plurality of liquid crystal display elements 230 are located in an enclosed space S formed between a first substrate 210 and a second substrate 220.

In the liquid crystal display device 200, the liquid crystal display element 230 serves as one pixel. The display device may be capable of higher-definition display by providing a TFT on an illuminator and providing a plurality of pixels capable of being driven independently from one another in one liquid crystal display element 230.

The first substrate 210 and the second substrate 220 are made of materials similar to the materials of the first and second substrates of the organic EL illuminating device 100 according to the first embodiment. The first substrate 210 and the second substrate 220 each have, for example, a length of about 250 mm, a width of about 444 mm, and a thickness of about 0.7 mm. At least one of these substrates (here, the first substrate 210) is a conductive wiring board provided with conductive wires 240 on the side facing the enclosed space S. Similar to the organic EL illuminating device 100 in the first embodiment, one end and the other end of each of the liquid crystal display elements 230 in the length direction are electrically connected to corresponding ones of the conductive wires 240. The liquid crystal display element 230 and its corresponding conductive wires 240 can be connected by connecting wirings 241 which are made of lead-free solder, silver paste, etc., and which are provided on the surface of the liquid crystal display element 230 which is opposite to the surface facing the conductive wiring board, as in the first embodiment.

FIG. 12 is a cross-sectional view of the liquid crystal display element 230.

The liquid crystal display element 230 has a structure in which a backlight unit 231, a polarizing plate 232, an insulating base member 233 which supports a TFT, a first electrode 234, an alignment film 235, a liquid crystal layer 236, an alignment film 235, a second electrode 237, a color filter layer 238, and a polarizing plate 232 are sequentially layered. Materials similar to the materials which form a known liquid crystal display device can be used as the materials for these layers.

In the liquid crystal display device 200 of the second embodiment, the plurality of conductive wires 240 formed on the conductive wiring board 210 do not intersect with each other. It is therefore possible to reduce the size and the thickness of the conductive wiring board 210, compared to the case where the conductive wires 240 are layered in a multilayer structure. Since the liquid crystal display device 200 is formed using this conductive wiring board 210, the size and the thickness of the liquid crystal display device as a whole can be reduced.

### Other Embodiments

In the first embodiment, the electro-optic device was described as an illuminating device. In the second embodiment, the electro-optic device was described as a display device. However, the electro-optic device may be, for example, an organic thin film solar cell, an organic transistor (an organic FET), etc. Further, in the first embodiment, the illuminating device was described as an organic EL illuminating device 100, but may be, for example, an illuminating device such as an inorganic EL illuminating device, a plasma illuminating device, a field emission lamp (FEL), etc. In the second embodiment, the display device was described as a liquid crystal display device 200, but may be, for example, a display device such as an organic EL display device, an inorganic EL display device, a plasma display device, an electrophoretic display (EPD) device, a field emission display (FED) device, etc. In these cases, as well, it is possible to reduce the size of the device as a whole by providing single-layer conductive wires on the conductive wiring board so as not to intersect with each other, and possible to form the conductive wiring board in simple procedures.

### EXAMPLES

An organic EL illuminating device was fabricated, and the organic EL illuminating device was driven by the methods described in Examples 1-13 below. The results are also shown in Table 1.

### Example 1

An organic EL illuminating device having a structure described in the first embodiment was fabricated. Here, each of the organic EL illuminators has a strip shape whose length is 160 mm and a width is 30 mm. Three types of illuminators, i.e., a red color illuminator, a green color illuminator, and a blue color illuminator, were prepared.

Glass substrates each having a length of 200 mm, a width of 200 mm, and a thickness of 0.7 mm were used as the first substrate and the second substrate. Conductive wires were formed on a surface of the first substrate in an atmosphere in which a degree of vacuum is 6×10⁻⁴ Pa. The thickness of each of the wires was 100 nm.

Voltages were applied to the respective conductive wires such that the illumination percentages of the red color illuminator, the green color illuminator, and the blue color illuminator would be 30%, 22%, and 48%, respectively. Here, the term “illumination percentage” refers to a percentage to a maximum current flowing in an anode or a cathode of the panel (where the duty cycle is 1/1). For example, when the maximum current flowing in the cathode is 200 mA, and a current of 60 mA flows at a duty cycle of 1/1, the illumination percentage is 60/200=30% (0.3).

In this structure, a daylight white color was emitted from the organic EL illuminating device as a whole. The chromaticity and the color temperature were measured using a luminance colorimeter BM-5A manufactured by TOPCON CORPORATION and a spectral radiance meter MCPD-7000 manufactured by Otsuka Electronics Co., Ltd. The result was that the light had a daylight white color whose chromaticity was (0.35, 0.32), and the color temperature was 5000 K. The luminance measured by the above devices was 5000 cd/m². The drive voltage was 7 V for the red color illuminator, 6 V for the green color illuminator, and 8 V for the blue color illuminator.

### Example 2

An organic EL illuminating device having the same structure as the organic EL illuminating device of Example 1 was used. Voltages were applied to the respective conductive wires such that the illumination percentages of the red color illuminator, the green color illuminator, and the blue color illuminator would be 44%, 28%, and 48%, respectively.

In this structure, a warm white color whose chromaticity is (0.42, 0.40) and color temperature is 3300 K was emitted from the organic EL illuminating device as a whole.

### Example 3

An organic EL illuminating device having the same structure as the organic EL illuminating device of Example 1 was used. Voltages were applied to the respective conductive wires such that the illumination percentages of the red color illuminator, the green color illuminator, and the blue color illuminator would be 30%, 22%, and 60%, respectively.

In this structure, a daylight color whose chromaticity is (0.31, 0.31) and color temperature is 6900 K was emitted from the organic EL illuminating device as a whole.

### Example 4

Different from Example 1 in which illuminators that emit three types of wavelengths, i.e., a red color, a green color, and a blue color were controlled independently of each other, an organic EL illuminating device in which illuminators that emit light having two types of wavelengths, i.e., an orange color illuminator and a blue color illuminator can be controlled independently of each other, was fabricated. Here, as an orange color light emitting dopant, a material represented by

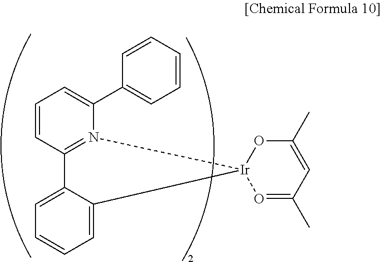

which is bis(2-phenylquinoline)(acetylacetonato)iridium(III)((2-phq)₂Ir(acac)) was used, and as a blue phosphorescent light emitting dopant, Firpic was used, to fabricate the respective illuminators.

This organic EL illuminating device was driven in Example 4. White light with a blue tinge which is closer to a daylight color and whose chromaticity is (0.30, 0.33) and color temperature is 7200 K was emitted from the organic EL illuminating device as a whole.

### Example 5

An organic EL illuminating device having the same structure as the organic EL illuminating device of Example 4 was used. The organic EL illuminating device was made to emit light such that the orange color illuminator was made to emit light as in Example 4, whereas no voltage was applied to the blue color illuminator so as not to emit light. Light whose chromaticity is (0.55, 0.45) was emitted from the organic EL illuminating device as a whole. The light intensity was about a half the light intensity of Example 4.

### Example 6

An organic EL illuminating device having the same structure as the organic EL illuminating device of Example 4 was used. The organic EL illuminating device was made to emit light such that the blue color illuminator was made to emit light as in Example 4, whereas no voltage was applied to the orange color illuminator so as not to emit light. Light whose chromaticity is (0.17, 0.27) was emitted from the organic EL illuminating device as a whole. The light intensity was about a half the light intensity of Example 4.

### Example 7

An organic EL illuminating device having the same structure as the organic EL illuminating device of Example 4 was used. The organic EL illuminating device was made to emit light such that the blue color illuminator was made to emit light as in Example 4, whereas twice the amount of voltage applied in Example 4 was applied to the orange color illuminator. A warm white color whose chromaticity is (0.40, 0.36) and color temperature is 3200 K was emitted from the organic EL illuminating device as a whole.

### Example 8

An organic EL illuminating device having the same structure as the organic EL illuminating device of Example 4 was used. The organic EL illuminating device was made to emit light such that the blue color illuminator was made to emit light as in Example 4, whereas half the amount of voltage applied in Example 4 was applied to the orange color illuminator. A white color whose chromaticity is (0.29, 0.29) and the color temperature is high, i.e., 8800 K, was emitted from the organic EL illuminating device as a whole.

### Example 9

An organic EL illuminating device which emits three types of wavelengths as in Example 1 was used. In this illuminating device, a red color illuminator was connected to every wire for the three wavelengths.

In this structure, a red color was emitted from the organic EL illuminating device as a whole. The light intensity was about three times the light intensity obtained by allowing light emission of only the red color illuminators of the organic EL illuminating device of Example 1.

### Example 10

An organic EL illuminating device which emits three types of wavelengths as in Example 1 was used. In this illuminating device, a green color illuminator was connected to every wire for the three wavelengths.

In this structure, a green color was emitted from the organic EL illuminating device as a whole. The light intensity was about three times the light intensity obtained by allowing light emission of only the green color illuminators of the organic EL illuminating device of Example 1.

### Example 11

An organic EL illuminating device which emits three types of wavelengths as in Example 1 was used. In this illuminating device, a blue color illuminator was connected to every wire for the three wavelengths.

In this structure, a blue color was emitted from the organic EL illuminating device as a whole. The light intensity was about three times the light intensity obtained by allowing light emission of only the blue color illuminators of the organic EL illuminating device of Example 1.

### Example 12

An organic EL illuminating device having the same structure as the organic EL illuminating device of Example 1 was used, and only a red color illuminator and a green color illuminator were made to emit light. In this structure, a yellow color, i.e., an intermediate color, of which the chromaticity is (0.44, 0.45) was emitted from the organic EL illuminating device as a whole.

### Example 13

An organic EL illuminating device having the same structure of the organic EL illuminating device of Example 1 was used, and the illumination percentage of each of the respective illuminators was freely varied between 0-100% with time. In this structure, light with gradational changes in the light intensity and the luminescent color was emitted from the organic EL illuminating device as a whole.

### Example 14

An organic EL illuminating device having the same structure as the organic EL illuminating device of Example 1 was modified so that the illumination percentage of each of the illuminators could be controlled by a remote controller. During the time when the organic EL illuminating device was turned on, the illumination percentage of each of the illuminators was freely selected from among 0-100% by a remote controller. Both the light intensity and the luminescent color can be set to desired values by the remote controller in the organic EL illuminating device as a whole, and it was found that the organic EL illuminating device had a light control function and a color tone control function.

TABLE 1

| Example | Illumination Percentage | | | Color | Others |
|---|---|---|---|---|---|
| 1 | Red | Green | Blue | Chromaticity (0.35, 0.32) | Luminance was 5000 cd/m² |
| | 30% | 22% | 48% | Color Temperature 5000 K | |
| | Drive Voltage | | | Daylight White Color | |
| | 7 V | 6 V | 8 V | | |
| 2 | Red | Green | Blue | Chromaticity (0.42, 0.40) | |
| | 44% | 28% | 48% | Color Temperature 3300 K | |
| | | | | Warm White Color | |
| 3 | Red | Green | Blue | Chromaticity (0.31, 0.31) | |
| | 30% | 22% | 60% | Color Temperature 6900 K | |
| | | | | Daylight Color | |

| | | | | |
|---|---|---|---|---|
| 4 | Orange | Blue | Chromaticity (0.30, 0.33) | |
| | | | Color Temperature 7200 K | |
| | | | White color with a blue tinge | |
| | | | closer to daylight color | |
| 5 | Orange | Blue | Chromaticity (0.55, 0.45) | Light Intensity was almost |
| | | 0% | | half the case of Example 4. |
| 6 | Orange | Blue | Chromaticity (0.17, 0.27) | Light Intensity was almost |
| | 0% | | | half the case of Example 4. |
| 7 | Orange | Blue | Chromaticity (0.40, 0.36) | |
| | Twice the case | | Color Temperature 3200 K | |
| | of Example 4 | | Warm White Color | |
| 8 | Orange | Blue | Chromaticity (0.29, 0.29) | |
| | Half the case | | Color Temperature 8800 K | |
| | of Example 4 | | White color light with high | |
| | | | color temperature | |

| 9 | Red | Red | Red | — | Light Intensity was about three |
|---|---|---|---|---|---|
| | | | | | times the case of Example 1. |
| 10 | Green | Green | Green | — | Light Intensity was about three |
| | | | | | times the case of Example 1. |
| 11 | Blue | Blue | Blue | — | Light Intensity was about three |
| | | | | | times the case of Example 1. |
| 12 | Red | Green | Blue | Chromaticity (0.44, 0.45) | |
| | | | 0% | Yellow-color emission | |
| 13 | Red | Green | Blue | — | gradationally changed |
| | varies between 0-100% | | | | |
| 14 | Red | Green | Blue | — | Light intensity and luminescent |

| | |
|---|---|
| freely selected during lighting | color could be freely controlled. |

### INDUSTRIAL APPLICABILITY

The present invention is useful as an electro-optic device, such as an organic EL device and a liquid crystal display device which have a conductive wiring board, and a method for manufacturing the electro-optic device.

### DESCRIPTION OF REFERENCE CHARACTERS

S enclosed space
100 organic EL illuminating device (electro-optic device)
110 first substrate (conductive wiring board)
120 second substrate (a substrate)
130 organic EL illuminator (optical element)
131 insulating base member
132, 234 first electrode (lower electrode)
133 organic EL layer (function layer)
134, 237 second electrode (upper electrode)
140 conductive wire
200 liquid crystal display device (electro-optic device)
230 liquid crystal display element (optical element)
233 insulating base member
236 liquid crystal layer (function layer)

1. An electro-optic device, comprising:
a conductive wiring board on one surface of which a plurality of conductive wires are arranged so as not to intersect with each other; and
a plurality of optical elements each of which is provided on the conductive wiring board, and in which an insulating base member, a lower electrode, a function layer, and an upper electrode are sequentially formed on the conductive wiring board, wherein
the lower electrode is electrically connected to one of the plurality of conductive wires,
the upper electrode is electrically connected to one of the plurality of conductive wires which is not connected to the lower electrode, and
each of the plurality of optical elements is provided such that part of the optical element overlaps with part of one or more of the conductive wires in plan view.

2. The electro-optic device of claim 1, wherein
the plurality of conductive wires are arranged so as to extend in parallel with each other.

3. The electro-optic device of claim 1, wherein
each of the plurality of optical elements has an elongated shape, and
the plurality of conductive wires are arranged so as to extend in a direction orthogonal to a length direction of the plurality of optical elements.

4. The electro-optic device of claim 1, wherein
the insulating base member is made of a flexible material.

5. The electro-optic device of claim 1, wherein
the conductive wiring board is made of a flexible material.

6. The electro-optic device of claim 1, wherein
the plurality of optical elements are placed in an enclosed space formed between the conductive wiring board and a substrate facing the conductive wiring board.

7. The electro-optic device of claim 1, wherein
the function layer is an organic EL layer, and
the plurality of optical elements are organic EL illuminators.

8. The electro-optic device of claim 7, wherein
each of the insulating base member and the lower electrode is made of an optically transparent material.

9. The electro-optic device of claim 7, wherein
the organic EL illuminators are placed in an enclosed space formed between the conductive wiring board and a substrate facing the conductive wiring board, and
at least one of the conductive wiring board or the substrate is made of an optically transparent material.

10. The electro-optic device of claim 7, wherein
a diffusion resin layer having a light diffusion function is provided to a light extraction side of each of the organic EL illuminators.

11. The electro-optic device of claim 10, wherein
the diffusion resin layer is a diffuser plate.

12. The electro-optic device of claim 7, wherein
a wavelength conversion layer for converting a wavelength of light is provided to the light extraction side of each of the organic EL illuminators.

13. The electro-optic device of claim 9, wherein
the space between the conductive wiring board and the substrate is filled with a heat dissipating resin whose heat conductivity is higher than a heat conductivity of air.

14. The electro-optic device of claim 8, wherein
the insulating base member is made of a material having a light diffusion property.

15. The electro-optic: device of claim 7, wherein
the organic EL layer includes a charge generation layer.

16. The electro-optic device of claim 7 used for illumination.

17. The electro-optic device of claim 16, wherein
the plurality of conductive wires are driven independently of each other, thereby making it possible to adjust light emission of the electro-optic device as a whole.

18. The electro-optic device of claim 7 used for a display.

19. The electro-optic device of claim 1, wherein
the plurality of optical elements are liquid crystal display elements in each of which the function layer is made of a liquid crystal layer, and each of which is further provided with a backlight unit on a surface closer to the insulating base member or on a surface of the upper electrode.

20. A method for manufacturing an electro-optic device including
a conductive wiring board on one surface of which a plurality of conductive wires are arranged so as not to intersect with each other; and
a plurality of organic EL elements each of which is provided on the conductive wiring board, and in which an insulating base member, a lower electrode, an organic EL layer, and an upper electrode are sequentially formed on the conductive wiring board, wherein
the lower electrode is electrically connected to one of the plurality of conductive wires,
the upper electrode is electrically connected to one of the plurality of conductive wires which is not connected to the lower electrode, and
each of the plurality of organic EL elements is provided such that part of the organic EL element overlaps with part of one or more of the conductive wires in plan view, the method comprising:
performing processes for forming the organic EL layer and the upper electrode on the insulating base member conveyed by a roll-to-roll method.
